(19) United States
(12) Patent Application Publication
(10) Pub. No.: US 2020/0078823 A1
(43) Pub. Date: Mar. 12, 2020

(54) PAINT SPREADING DEVICE

(71) Applicant: Wuhan China Star Optoelectronics Semiconductor Display Technology Co., Ltd., Wuhan, Hubei (CN)

(72) Inventors: Fenghao CAI, Shenzhen, Guangdong (CN); JEOUNG KWEN NOH, Shenzhen, Guangdong (CN); DONGHWAN KIM, Shenzhen, Guangdong (CN); YOUNG SU KIM, Shenzhen, Guangdong (CN); CHIENLIN WU, Shenzhen, Guangdong (CN); Xuwen CAO, Shenzhen, Guangdong (CN)

(73) Assignee: Wuhan China Star Optoelectronics Semiconductor Display Technology Co., Ltd., Wuhan, Hubei (CN)

(21) Appl. No.: 15/745,430

(22) PCT Filed: Nov. 24, 2017
(86) PCT No.: PCT/CN2017/112937

§ 371 Date: Jan. 16, 2018

(30) Foreign Application Priority Data
Jun. 28, 2017 (CN) 201710513523.X

(51) Int. Cl. B05D 1/32; B05C 3/20; B05D 1/02

(52) U.S. Cl. CPC B05D 1/32; G03F 7/707; B05D 1/02; B05C 3/20

(57) ABSTRACT

Provided is a paint spreading device, comprising a moving stage for bearing a substrate, a mask having a hollow pattern, an alignment system and a paint nozzle, wherein the mask is above the moving stage and has a gap with the substrate, an orthographic projection of the mask on the moving stage completely covers the substrate, the alignment system is above the moving stage at one side of the mask, the paint nozzle is right above the mask to spread paint on the mask.

### CROSS REFERENCE

This application claims the priority of Chinese Patent Application No. 201710513523X, entitled “Paint spreading device”, filed on Jun. 28, 2017, the disclosure of which is incorporated herein by reference in its entirety.

### FIELD OF THE INVENTION

The present invention relates to a paint manufacturing field, and more particularly to a paint spreading device.

### BACKGROUND OF THE INVENTION

The paint spreading process is often used in the processes of electronic industry. The paint spreading process is used in the electronic processes of semiconductors, displays and touch panels. There are many paint spreading processes at present. The traditional paint spreading devices may have roller printing, mesh printing and relief printing. With the cost saving development of the electronic industry, some manufacturers begin to use ink-jet printing for paint spreading process. The ink-jet printing can possess property of printing on demand. The rough pattern may be directly printed and such printing saves the material cost. However, the accuracy of the paint spreading is difficult to be ensured.

### SUMMARY OF THE INVENTION

The present invention provides a paint spreading device with high paint spreading accuracy.

The paint spreading device of the present application comprises a moving stage for bearing a substrate, a mask having a hollow pattern, an alignment system and a paint nozzle, wherein the mask is above the moving stage and has a gap with the substrate, an orthographic projection of the mask on the moving stage completely covers the substrate, the alignment system is above the moving stage at one side of the mask, the paint nozzle is right above the mask to spread paint on the mask.

The paint spreading device comprises a bearing frame, the bearing frame is supported above the moving stage, the bearing frame comprises bearing sides, and a periphery of the mask is supported by the bearing sides. The bearing frames comprise vacuum holes to suck and fix the mask so as to prevent the mask from being moved during use to affect the alignment accuracy.

Both the substrate and the mask comprise alignment marks for alignment of the substrate and the mask.

The alignment marks are static marks or position sensors.

The moving stage comprises a stage and a moving part for supporting and moving the stage, the moving part moves the stage to move relative to the mask to achieve the alignment of the substrate and the mask. The stage comprises vacuum holes to suck the substrate to prevent the substrate from being moved.

The moving part comprises a sliding rail and a sliding groove matched with the sliding rail and the stage is supported on the sliding rail or the sliding groove; or the moving part comprises a leading screw and a sliding block slidably arranged at the leading screw and the stage is supported on the sliding block.

The mask comprises the hollow pattern consisted of a plurality of hollow regions, an area spread by the paint nozzle through the hollow regions is larger than an area of the hollow regions.

An equality of a pattern after the paint nozzle spreads on the substrate with the mask is adjusted by adjusting the gap.

Paint spread by the paint nozzle is ink.

The paint spreading device comprises a controller, the controller is connected to the alignment system, the bearing frame and the moving stage to control the alignment system to align the mask on the bearing frame and the substrate on the moving stage.

In the paint spreading device of the present invention, the alignment system is used to move the stage to implement multiple alignments to the mask and the substrate. Meanwhile, the distance (gap) between the mask and the substrate can be adjusted to make the spreading area accurate to realize the accurate alignment to ensure the quality of spread printing.

### BRIEF DESCRIPTION OF THE DRAWINGS

The structural features and effects of the present invention will be more clearly described, which will now be described in detail with reference to the accompanying drawings and specific embodiments.

FIG. 1 is a diagram of a paint spreading device according to the present invention.

### DETAILED DESCRIPTION OF PREFERRED EMBODIMENTS

For better explaining the technical solution and the effect of the present invention, the present invention will be further described in detail with the accompanying drawings in the specific embodiments. The figures are for illustrative purposes only and are illustrative only but not to be construed as limiting the present application.

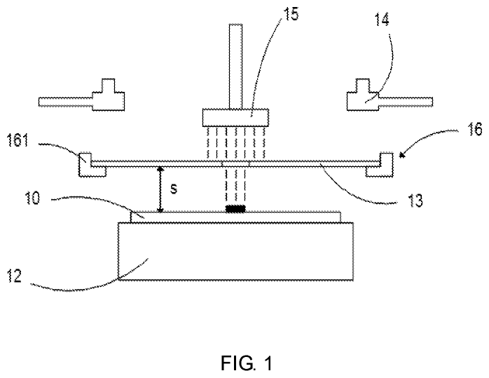

The present invention provides a paint spreading device, applied for the formation of the structural patterns for the liquid crystal displays and touch panels. In this embodiment, the paint spreading means ink spreading for forming the structural patterns on the glass substrate of the liquid crystal panel. Please refer to FIG. 1. The paint spreading device comprises a moving stage 12 for bearing a substrate 10, a mask 13 having a hollow pattern, an alignment system 14 and a paint nozzle 15. The mask 13 is above the moving stage 12 and has a gap S with the substrate 10, an orthographic projection of the mask 13 on the moving stage 12 completely covers the substrate 10, the alignment system 14 is above the moving stage 12 at one side of the mask 13, the paint nozzle 15 is right above the mask 13 to spread paint on the mask 13. Paint spread by the paint nozzle 15 is ink. The mask 13 is a metal mask.

The alignment system 14 can be a charge coupled device (CCD) image sensor. The alignment system comprises a camera, a graphics processor and a moving component (not shown). Before the nozzle starts to spread, the moving component moves the camera around the alignment marks to shoot, to obtain data and to implement alignment. After the alignment operation is accomplished, the moving component moves the camera away from the mask to prevent the camera from interfering with the nozzle movement and the spreading. In this embodiment, the two alignment systems are used to implement the alignment. The two alignment systems are respectively at two opposite sides of the mask 13. After the alignment is accomplished, the alignment systems at two sides are moved away from the top of the mask 13. The alignment system 14 implements the accurate alignment for the position of the mask 13 relative to the substrate 10.

The paint spreading device uses the mask 13 as a master. The paint nozzle 14 is first moved to a position, which requires spreading above the mask to spread the paint on the mask 13. The hollow portion of the pattern of the mask exposes the surface of the substrate 10 to be filled with the paint, which is equivalent to the transfer-printing. Thus, the portion, which does not require to be spread, is covered by the mask such that the transfer-printed pattern on the substrate 10 will be more accurate.

The paint spreading device comprises a bearing frame 16, the bearing frame 16 is supported above the moving stage 12, the bearing frame 16 is a quadrilateral frame or a polygonal frame and comprises bearing sides 161, a periphery of the mask 13 is supported by the bearing sides 161 and the pattern of the mask 13 is exposed. Meanwhile, the vacuum holes on the bearing frame 16 are used to suck the mask 13 to prevent the mask from being moved to affect the alignment accuracy.

The paint spreading device comprises a controller, the controller is connected to the alignment system 14, the bearing frame 16 and the moving stage to control the alignment system 14 to align the mask 13 on the bearing frame 16 and the substrate 10 on the moving stage 12. The controller controls the initial positioning of the bearing frame 16 and the moving stage 12 mainly according to the human eyes to recognize the positioning marks or according to the data delivered to the controller by the position sensors for controlling the movements of the bearing frame 16 and the moving stage 12. Then, the alignment system 14 is used to implement accurate positioning for the position of the mask 13 relative to the substrate 10 and then, delivers the data to the controller. Then, the controller adjusts the position of the moving stage 12 to achieve the adjustment to the position of the substrate 10 to ensure that the orthographic projection of the mask completely covers the substrate 10. Meanwhile, the pattern of the mask is aligned to the pattern formation region of the substrate 10.

The mask 13 having the pattern to be formed on the substrate 10 is installed on the bearing frame 16 and then, the vacuum suction is implemented to fix the mask 13. After the substrate 10 to be spread is arranged on the moving stage 12, the vacuum suction is implemented to fix the substrate 10. Then, the gap S of substrate 10 relative to the mask is adjusted. Specifically, the stage comprises a lifting part. The lifting part drives the stage to move up and down relative to the mask to achieve the gap adjustment for the substrate and the mask.

The controller adjusts the positions of the bearing frame 16 and the moving stage 12 to initially align the mask 13 and the substrate 10. Then, the controller controls the alignment system 14 to further align the positions of the substrate 10 and the mask 13 and to adjust the position of the moving stage 12, again so that the region for spreading of the substrate 10 is accurately aligned with the pattern region of the mask 13. Then the paint nozzle 15 is controlled to move to the position above the mask, which requires spreading to implement spreading. The controller controls the spreading volume of the nozzle to adjust the thickness of the ink spread on the substrate to ensure that the spread film thickness satisfies the requirement. The nozzle spreads the ink on the substrate 10 through the hollow area of the mask. The mask 13 acts as a master. Ultimately, the pattern on the mask is printed on the substrate to realize the pattern transferring. During spreading, the controller can adjust the spreading volume and the position of the nozzle 15 to adjust the spreading area of the nozzle on the mask 13. Moreover, it is possible to make the spreading area of each pattern accurate. The distance between the nozzle 15 and the mask 13 is controllable and the flatnesses of the mask and the substrate can be ensured. Thus, the gap S of the mask 13 and the substrate 10 can be adjusted to be very small, and can preferably be 50 μm. Thus, the ink spreading distance of the gap of the mask 13 and the substrate 10 can be reduced to ensure that the mask 13 as a master is printed on the substrate 10 more accurately and to ensure the equality of the entire spreading for guaranteeing the complete spreading of the pattern. The ink is spread on the mask 13 through the nozzle. The ink in the pattern forms the ink pattern on the substrate 10.

Namely, the equality and accuracy of the pattern on the substrate 10 after being spread by the paint nozzle 15 is adjusted by adjusting the gap S. For instance, as the mask 13 is moved away from the substrate 12, i.e. the distance of the gap S is increased, the range that the paint nozzle 15 spreads on the substrate 10 through the mask 13 is increased. Instead, the range is decreased. Then, the pattern size formed on the substrate can be accurately adjusted. Preferably, the spreading area of the paint nozzle 15 on the mask is slightly larger than the area of the hollow patterns of the mask 13 to ensure that the hollow positions are all spread.

Furthermore, the mask 13 comprises the hollow pattern consisted of a plurality of hollow regions, an area spread by the paint nozzle 15 through the hollow regions is larger than an area of the hollow regions such that the spreading completeness can be ensured.

Furthermore, both the mask 13 and the substrate 10 comprise alignment marks for alignment of the mask 13 and the substrate 10. The alignment marks are static marks (such as tick marks) or position sensors. For instance, the position sensors of the mask 13 and the substrate 10 deliver data to the controller. The controller controls the moving stage 12 to move.

The moving stage 12 comprises a stage 121 and a moving part (not shown) for supporting and moving the stage 121, the moving part moves the stage 121 to move relative to the mask 13 to achieve the alignment of the substrate 10 and the mask 13. The moving part comprises a sliding rail and a sliding groove matched with the sliding rail and the stage is supported on the sliding rail or the sliding groove; or the moving part comprises a leading screw and a sliding block slidably arranged at the leading screw and the stage is supported on the sliding block.

In the paint spreading device of the present invention, the alignment system is used to move the stage to implement multiple alignments to the mask and the substrate. Meanwhile, the distance (gap) between the mask and the substrate can be adjusted to make the spreading area accurate to realize the accurate alignment to ensure the quality of spread printing.

Above are only specific embodiments of the present invention, the scope of the present invention is not limited to this, and to any persons who are skilled in the art, change or replacement which is easily derived should be covered by the protected scope of the invention. Thus, the protected scope of the invention should go by the subject claims.

What is claimed is:

1. A paint spreading device, comprising a moving stage for bearing a substrate, a mask having a hollow pattern, an alignment system and a paint nozzle, wherein the mask is above the moving stage and has a gap with the substrate, an orthographic projection of the mask on the moving stage completely covers the substrate, the alignment system is above the moving stage at one side of the mask, the paint nozzle is right above the mask to spread paint on the mask.

2. The paint spreading device according to claim 1, wherein the paint spreading device comprises a bearing frame, the bearing frame is supported above the moving stage, the bearing frame comprises bearing sides, a periphery of the mask is supported by the bearing sides.

3. The paint spreading device according to claim 2, wherein the substrate and the mask comprise alignment marks for alignment of the substrate and the mask.

4. The paint spreading device according to claim 3, wherein the alignment marks are static marks or position sensors.

5. The paint spreading device according to claim 3, wherein the moving stage comprises a stage and a moving part for supporting and moving the stage, the moving part moves the stage to move relative to the mask to achieve the alignment of the substrate and the mask.

6. The paint spreading device according to claim 5, wherein the moving part comprises a sliding rail and a sliding groove matched with the sliding rail and the stage is supported on the sliding rail or the sliding groove; or the moving part comprises a leading screw and a sliding block slidably arranged at the leading screw and the stage is supported on the sliding block.

7. The paint spreading device according to claim 1, wherein the mask comprises the hollow pattern consisted of a plurality of hollow regions, an area spread by the paint nozzle through the hollow regions is larger than an area of the hollow regions.

8. The paint spreading device according to claim 1, wherein an equality of a pattern formed on the substrate with the mask is adjusted by adjusting the gap.

9. The paint spreading device according to claim 8, wherein paint spread by the paint nozzle is ink.

10. The paint spreading device according to claim 2, wherein the paint spreading device comprises a controller, the controller is connected to the alignment system, the bearing frame and the moving stage to control the alignment system to align the mask on the bearing frame and the substrate on the moving stage.
